(19) United States
(12) Patent Application Publication
(10) Pub. No.: US 2015/0007878 A1
(43) Pub. Date: Jan. 8, 2015

(54) SOLAR CELL

(71) Applicant: NEO SOLAR POWER CORP., Hsinchu (TW)

(72) Inventors: Meng-Hsiu WU, Hsinchu (TW); Wei-Ming CHEN, Hsinchu (TW); Chun-Ming WU, Hsinchu (TW); Shang -Yu CHUANG, Hsinchu (TW); Yu-Wei TAI, Hsinchu (TW)

(21) Appl. No.: 14/314,635

(22) Filed: Jun. 25, 2014

(30) Foreign Application Priority Data
Jul. 3, 2013 (TW) 102123885

(51) Int. Cl. H01L 31/0224

(52) U.S. Cl. CPC H01L 31/022433
USPC 136/256

(57) ABSTRACT

A solar cell includes a solar cell body, a plurality of busbars and a plurality of finger electrodes. The number of the finger electrodes is adjusted according to a width of the finger electrodes, a gap between the finger electrodes and a laid length of the solar cell body, such that a photovoltaic conversion efficiency of the solar cell can be substantially enhanced.

This application claims the benefit of Taiwan Patent Application Serial No. 102123885, filed Jul. 3, 2013, the subject matter of which is incorporated herein by reference.

### BACKGROUND OF INVENTION

1. Field of the Invention

The invention relates to a solar cell, and more particularly to the solar cell that utilizes tiny finger electrodes with an extreme small width so as able to enhance the photoelectric conversion efficiency of the solar cell.

2. Description of the Prior Art

Generally speaking, the current solar cell has a structure formed by having plural finger electrodes to be laid on the solar cell body so as to utilize the finger electrodes to collect the induced electric currents resulted from the solar cell body bombarded by lights. In the setup, the busbars are used to accumulate the electric currents collected by individual finger electrodes. Thereby, the photo-induced electric current can then be led to further application through the busbars.

In the art of the solar cells, the electrodes are usually structured to both surfaces, the light-receiving surface and the opposing back-light surface, of the solar cell body. However, the finger electrodes and the busbars on the light-receiving surface might shadow the solar cell body. Hence, additional work is needed to optimize the width and the quantity of the finger electrodes on the light-receiving surface. Empirically, it is found that a linear relationship between the width and the quantity of the finger electrodes exists. Namely, in the case that the width of the finger electrode decreases, the required quantity of the finger electrodes is increased. In addition, the photoelectric conversion efficiency of the solar cell is increased as well.

Currently, in the art of the solar cells, the width of the finger electrode is for practicing is mainly distributed from 50 to 150 μm, while the quantity of the finger electrodes is about 50 to 100.

According to the prior art, while the width of the finger electrode is 150 μm, the preferable quantity of the finger electrodes is 50. Further, while the width of the finger electrode is 50 μm, the preferable quantity of the finger electrodes is 100.

In the European Patent No. EP2309547B1, though some spacing values and specific ratios between the finger electrode and its width are disclosed, yet the technique of how to enhance the photovoltaic conversion efficiency of the solar cell by rearranging the quantity of the finger electrodes while the finger electrode has an extreme small width is not taught or mentioned anyhow. In this disclosure, it is noted that, while the width of the finger electrode is extremely small, an irrelevant quantity for the finger electrodes would be applied, and thus the overall photovoltaic conversion efficiency would be degraded.

In the manufacturing of the finger electrodes, the finger electrodes are usually screen-printed on the solar cell body. For example, in this manufacturing process, the silver paste is firstly painted onto a mesh, then the silver paste would fill into the predetermined spacing pattern on the mesh, and thus the silver paste can be transferred to print onto the solar cell body. Obviously, the width of the finger electrode is related to the formation of the predetermined spacing pattern. In the art, the width of the finger electrode is from 50 to 150 μm, but the corresponding preferred quality is unpredictable.

As described above, the width of the finger electrode is limited due to process. However, according to the trend of optimal performance, when the width of the finger electrodes is less than 50 μm (i.e. an extreme small size for the width of the finger electrode), the screen-printing paste would have a high risk to be inhomogeneously distributed on the surface of the solar cell; such that a jammed screen can be foreseen and broken lines of the finger electrodes can be expected. To amend the foregoing problem caused by the narrow finger electrodes, the number (quantity) of the finger electrodes shall be increased so that enough pathways would be provided for accumulating the induced electric currents. However, too many finger electrodes would result in a high shadow area and a degrading performance. Thus, currently, the width of the finger electrodes for the solar cells is mainly ranged from 50 to 150 μm and the quantity thereof is generally between 50 and 80.

As described above, in the technique of the screen printing, an optimal performance between the extreme-narrow width and the quantity of the finger electrode is still not achieved. Also, according to the current technique of the screen printing, there is no effective way in minimizing the width of the finger electrode so as to enhance the photovoltaic conversion efficiency of the solar cells.

### SUMMARY OF THE INVENTION

In view of the foregoing problems in the prior art, the present invention is to provide a solar cell that a thorough consideration upon the width of the finger electrode, the spacing for neighboring finger electrodes, and the layout of the solar cell body for locating an preferred quantity of the finger electrodes can be provided and thereby the photovoltaic conversion efficiency of the solar cell can be enhanced.

In the present invention, the solar cell comprises a solar cell body, a plurality of busbars and a plurality of the finger electrodes.

The solar cell body includes at least a layout area further having a first direction and a second direction perpendicular to the first direction, and the layout area has a laid length L along the first direction. The busbars are evenly distributed on the layout area in a manner of parallel to the first direction and extending individual ends thereof toward the second direction. The finger electrodes are also evenly distributed on the layout area in a manner of parallel to the second direction and perpendicular to the first direction. An N stands for a quantity of the finger electrodes. The width W of the finger electrode is from 10 μm to 50 μm. The spacing G of any two neighboring finger electrodes is from 332 μm to 1899 μm. In the present invention, the relationship among the laid length L, the quantity N of the finger electrodes, the width W and the spacing G can be interpreted by the equation of N×(W+G)−G=L.

In one embodiment of the present invention, in the case that the number of the busbars is 2 and the width W thereof is ranged from 10 to 20 μm, the spacing G is preferably ranged from 332 μm to 795 μm, and the quantity N of the finger electrodes is preferably ranged from 190 to 450.

In one embodiment of the present invention, in the case that the number of the busbars is 2 and the width W thereof is from 20 to 30 μm, the spacing G is preferably ranged from 652 μm to 1077 μm, and the quantity N of the finger electrodes is preferably ranged from 140 to 230.

In one embodiment of the present invention, in the case that the number of the busbars is 2 and the width W thereof is from 30 to 40 μm, the spacing G is preferably ranged from 881 μm to 1373 μm, and the quantity N of the finger electrodes is preferably ranged from 110 to 170.

In one embodiment of the present invention, in the case that the number of the busbars is 2 and the width W thereof is from 40 to 50 μm, the spacing G is preferably ranged from 1067 μm to 1588 μm, and the quantity N of the finger electrodes is preferably ranged from 95 to 140.

In one embodiment of the present invention, in the case that the number of the busbars is 3 and the width W thereof is from 10 to 20 μm, the spacing G is preferably ranged from 458 μm to 1014 μm, and the quantity N of the finger electrodes is preferably ranged from 150 to 330.

In one embodiment of the present invention, in the case that the number of the busbars is 3 and the width W thereof is from 20 to 30 μm, the spacing G is preferably ranged from 794 μm to 1383 μm, and the quantity N of the finger electrodes is preferably ranged from 110 to 190.

In one embodiment of the present invention, in the case that the number of the busbars is 3 and the width W thereof is from 30 to 40 μm, the spacing G is preferably ranged from 1003 μm to 1690 μm, and the quantity N of the finger electrodes is preferably ranged from 90 to 150.

In one embodiment of the present invention, in the case that the number of the busbars is 3 and the width W thereof is from 40 to 50 μm, the spacing G is preferably ranged from 1253 μm to 1783 μm, and the quantity N of the finger electrodes is preferably ranged from 85 to 120.

In one embodiment of the present invention, in the case that the number of the busbars is 4 and the width W thereof is from 10 to 20 μm, the spacing G is preferably ranged from 522 μm to 1174 μm, and the quantity N of the finger electrodes is preferably ranged from 130 to 290.

In one embodiment of the present invention, in the case that the number of the busbars is 4 and the width W thereof is from 20 to 30 μm, the spacing G is preferably ranged from 891 μm to 1526 μm, and the quantity N of the finger electrodes is preferably ranged from 100 to 170.

In one embodiment of the present invention, in the case that the number of the busbars is 4 and the width W thereof is from 30 to 40 μm, the spacing G is preferably ranged from 1077 μm to 1690 μm, and the quantity N of the finger electrodes is preferably ranged from 90 to 140.

In one embodiment of the present invention, in the case that the number of the busbars is 4 and the width W thereof is from 40 to 50 μm, the spacing G is preferably ranged from 1372 μm to 1899 μm, and the quantity N of the finger electrodes is preferably ranged from 80 to 110.

In one embodiment of the present invention, in the case that the number of the busbars is 5 and the width W thereof is from 10 to 20 μm, the spacing G is preferably ranged from 562 μm to 1274 μm, and the quantity N of the finger electrodes is preferably ranged from 120 to 270.

In one embodiment of the present invention, in the case that the number of the busbars is 5 and the width W thereof is from 20 to 30 μm, the spacing G is preferably ranged from 948 μtm to 1526 μm, and the quantity N of the finger electrodes is preferably ranged from 100 to 160.

In one embodiment of the present invention, in the case that the number of the busbars is 5 and the width W thereof is from 30 to 40 μm, the spacing G is preferably ranged from 1163 μm to 1690 μm, and the quantity N of the finger electrodes is preferably ranged from 90 to 130.

In one embodiment of the present invention, in the case that the number of the busbars is 5 and the width W thereof is from 40 to 50 μm, the spacing G is preferably ranged from 1372 μm to 1899 μm, and the quantity N of the finger electrodes is preferably ranged from 80 to 110.

In one embodiment of the present invention, the solar cell body has a plurality of the layout areas, and the length of the solar cell body along the first direction is no larger than the sum of all the laid lengths of the plurality of the layout areas.

In one embodiment of the present invention, the solar cell body has a plurality of lateral sides, in which a buffer space locates between the layout area and the lateral sides. Preferably, the buffer space has a width of 0.1-2 mm.

Accordingly, upon the limitation of the present invention in the width of the finger electrode and the spacing between any two neighboring finger electrodes, different widths of the finger electrode can match to different spacings, and also the quantity of the finger electrodes can be adjusted according to various solar cell bodies. Upon such an arrangement, the photovoltaic conversion efficiency of the solar cell can be substantially enhanced.

All these objects are achieved by the solar cell described below.

### BRIEF DESCRIPTION OF THE DRAWINGS

The present invention will now be specified with reference to its preferred embodiment illustrated in the drawings, in which:

FIG. 1 is a schematic view of a preferred exemplary embodiment of the solar cell in accordance with the present invention;

FIG. 2 is an enlarged view of area A of FIG. 1; and

FIG. 3 shows the relationship between the width of the finger electrode and the quantity of the finger electrodes in accordance with the present invention.

### DESCRIPTION OF THE PREFERRED EMBODIMENT

The invention disclosed herein is directed to a solar cell. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

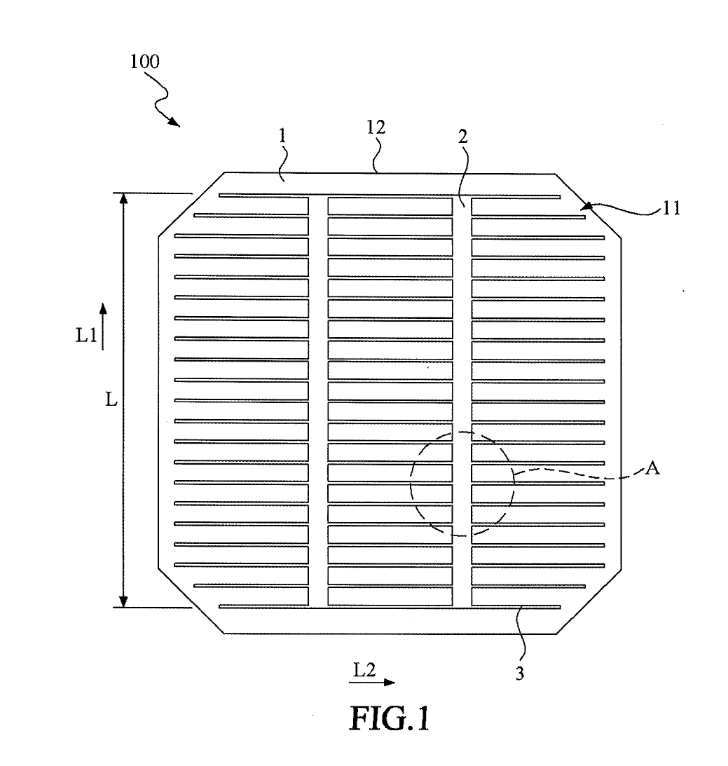

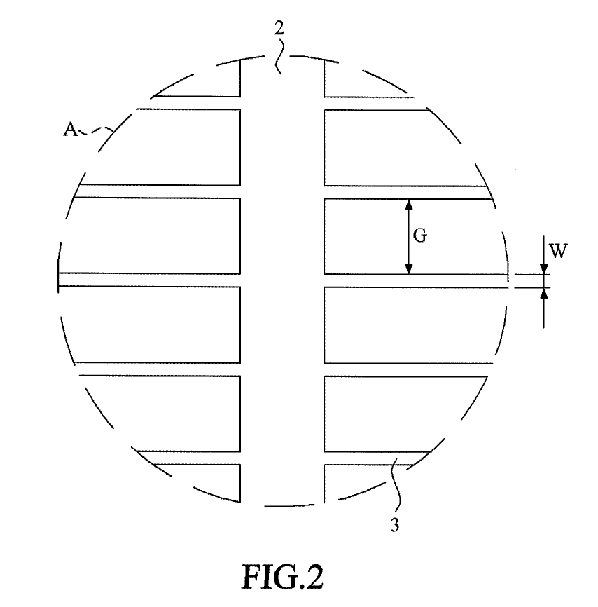

Refer to FIG. 1 and FIG. 2, in which FIG. 1 is a schematic view of an exemplary embodiment of the solar cell in accordance with the present invention, and FIG. 2 is an enlarged view of area A of FIG. 1. As shown, the solar cell 100 includes a solar cell body 1, two busbars 2 and a plurality of finger electrodes 3 (some shown in the figure).

The solar cell body 1 includes a layout area 11 and eight lateral sides 12. The layout area 11 has a laid length L along a first direction L1. The area between the layout area 11 and the lateral sides 12 is defined as a buffer space. The busbars 2 extend along the first direction L1 and are evenly parallel distributed on the solar cell body 1 with respect to a second direction L2, which is perpendicular to the first direction L1. On the other hand, the finger electrodes 3 are evenly parallel distributed on the solar cell body 1 with respect to the first direction L1, and each of the finger electrodes 3 is electrically connected to the corresponding busbar 2.

In this embodiment, the quantity of the finger electrodes 3 is denoted by a N, the finger electrode 3 has a width W ranged from 10 μm to 50 μm, and the spacing G for any two neighboring finger electrodes 3 is from 332 μm to 1899 μm. In particular, the quantity N of the finger electrodes 3, the width W of the individual finger electrode 3, the laid length L of the individual finger electrode 3, and the spacing G to separate the neighboring finger electrodes 3 satisfy the equation N x (W+G)−G=L. In this embodiment, the solar cell body 1 is formed as a 156 mm×156 mm square, the laid length L is 154,000 μm, the buffer space is 1 mm, the width W is 10 μm, and the spacing G is 336 μm. Therefore, according to the foregoing equation, the quantity N is 410. Namely, for the solar cell body 1 having the width W of the finger electrode 3 to be 10 μm and the laid length L thereof to be 154,000 μm, the spacing G for the finger electrodes 3 is 366 μm, preferably, and the corresponding quantity N of the finger electrodes 3 is about 410.

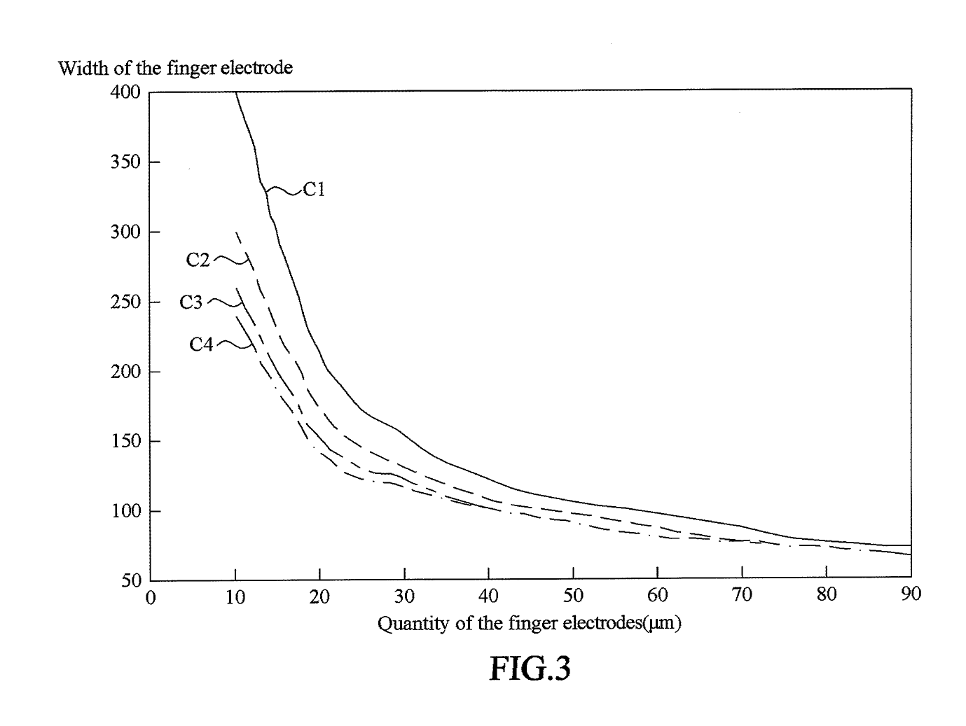

Refer now to FIG. 1 through FIG. 3, in which FIG. 3 shows the relationship between the width W of the finger electrode and the quantity N of the finger electrodes in accordance with the present invention. Specifically, the lines C1 stand for the finger electrodes 3 in the solar cell 100 of FIG. 1 with two busbars 2. Data for C1 are discretely listed in the following table.

| | | | | | | | | | |
|---|---|---|---|---|---|---|---|---|---|
| W | 10 | 20 | 30 | 40 | 50 | 60 | 70 | 80 | 90 |
| (μm) | | | | | | | | | |
| N of | 410 | 210 | 155 | 125 | 105 | 95 | 85 | 80 | 75 |
| line C1 | | | | | | | | | |

Refer to the above table and FIG. 3, it is obvious that, in the case that the width W of the finger electrode 3 is from 50 μm to 90 μm, the preferred quantity N is linearly varied from 75 (at W=90 μm) to 105 (at W=50 μm). According to this change rate, the quantity N for a W between 10 to 30 μm shall be theoretically ranged from 118 to 133, but actually the quantity N of the finger electrodes for the W less than 50 μm deviates from the trend established for the W range of 50 to 90 μm. From the above table and FIG. 3, if W is from 10 to 20 μm, the quantity N of the finger electrodes is preferably ranged from 190 to 450, and the corresponding spacing G is from 332 to 795 μm. On the other hand, if W=20 to 30 μm, the quantity N of the finger electrodes is preferably ranged from 140 to 230, and the corresponding spacing G is from 652 to 1077 μm.

In this embodiment, for the solar cell with two busbars, the preferable quantity N of the finger electrodes for W=10 μm, 20 μm, 30 μm and 40 μm is 410, 210, 155 and 125, respectively; which is totally different to the conventional prediction of 118 to 133.

As described above, for the difficulty in manufacturing the extreme-thin finger electrodes, according to the current art in providing the quantity N based on the data of W=50 to 90 μm, it is found that, for W<40 μm, the photoelectric conversion efficiency of the solar cell wouldn't have a significant increase even that the trend for quantity N is an increasing line. Therefore, development for the extreme-thin finger electrodes is overlook. Nevertheless, according to the foregoing embodiment of the present invention upon the solar cell with the finger electrodes having a common width W less than 50 μm, it is found that, when W is smaller than 40 μm (W<40 μm), the quantity N of the finger electrodes shall be significantly increased so as to enhance substantially the photoelectric conversion efficiency. As described above, the preferred quantity N of the finger electrodes would be more than expected. Hence, as W<40 μm and the preferred quantity of the finger electrodes applied to the solar cell in accordance with the present invention, the photoelectric conversion efficiency is significantly enhanced and definitely worthy for inventing on the extreme-thin (W<40 μm) finger electrodes.

Please refer to FIG. 3, in which lines C2, C3 and C4 stand for the embodiments that applying three, four and five busbars, respectively, for the solar cell in accordance with the present invention. Following table shows discretely data for lines C2, C3 and C4.

| | | | | | | | | | |
|---|---|---|---|---|---|---|---|---|---|
| W | 10 | 20 | 30 | 40 | 50 | 60 | 70 | 80 | 90 |
| (μm) | | | | | | | | | |
| N of | 300 | 170 | 130 | 107 | 95 | 85 | 75 | 70 | 65 |
| line C2 | | | | | | | | | |
| N of | 260 | 150 | 120 | 100 | 90 | 80 | 75 | 70 | 65 |
| line C3 | | | | | | | | | |
| N of | 240 | 140 | 115 | 100 | 90 | 80 | 75 | 70 | 65 |
| line C4 | | | | | | | | | |

Refer to FIG. 3 and the above table for the embodiment C2 with three busbars. In the case that the width W is 10 μm, 20 μm, 30 μm or 40 μm, the preferred quantity N is 300, 170, 130 or 107, respectively. Hence, according to the present invention, in the case that the width W is from 10 to 20 μm, the preferred quantity N is from 150 to 330, and the spacing G is from 458 μm to 1014 μm. In the case that the width W is from 20 to 30 μm, the preferred quantity N is from 110 to 190, and the spacing G is from 794 μm to 1383 μm. In the case that the width W is from 30 to 40 μm, the preferred quantity N is from 90 to 150, and the spacing G is from 1003 μm to 1690 μm.

Refer to FIG. 3 and the above table for the embodiment C3 with four busbars. In the case that the width W is 10 μm, 20 μm, 30 μm or 40 μm, the preferred quantity N is 260, 150, 120 or 100, respectively. Hence, according to the aforesaid equation, in the case that the width W is from 10 to 20 μm, the preferred quantity N is from 130 to 290, and the spacing G is from 522 μm to 1174 μm. In the case that the width W is from 20 to 30 μm, the preferred quantity N is from 100 to 170, and the spacing G is from 891 μm to 1526 μm. In the case that the width W is from 30 to 40 μm, the preferred quantity N is from 90 to 140, and the spacing G is from 1077 μm to 1690 μm.

Refer to FIG. 3 and the above table for the embodiment C4 with five busbars. In the case that the width W is 10 μm, 20 μm, 30 μm or 40 μm, the preferred quantity N is 240, 140, 115 or 100, respectively. Hence, according to the aforesaid equation, in the case that the width W is from 10 to 20 μm, the preferred quantity N is from 120 to 270, and the spacing G is from 562 μm to 1274 μm. In the case that the width W is from 20 to 30 μm, the preferred quantity N is from 100 to 160, and the spacing G is from 948 μm to 1526 μm. In the case that the width W is from 30 to 40 μm, the preferred quantity N is from 90 to 130, and the spacing G is from 1163 μm to 1690 μm.

Apparently, by providing the solar cell in accordance with the present invention, the width of the finger electrodes is reduced to an extreme thin scale so as to optimize the laid number and the laid spacing, such that the photovoltaic conversion efficiency of the solar cell can be improved.

In addition, the quantity of the busbars in accordance with the present invention is adjusted according to the quantity of the finger electrodes so as to obtain a preferred arrangement of the finger electrodes.

These and other features of the present invention will be readily apparent to persons of ordinary skill in the art upon reading the entirety of this disclosure, which includes the accompanying drawings and claims.

What is claimed is:

1. A solar cell, comprising:
a solar cell body, including at least one layout area further having a first direction and a second direction perpendicular to the first direction, the layout area having a laid length along the first direction;
a plurality of busbars, evenly distributed on the layout area in a manner of parallel to the first direction and extending individual ends thereof toward the second direction; and
a plurality of finger electrodes, protruded from at least one side of the plurality of busbars, evenly distributed on the layout area in a manner of parallel to the second direction and perpendicular to the first direction;
wherein an N stands for a quantity of the finger electrodes, a width W of the finger electrode is from 10 μm to 50 μm, a spacing G of any two neighboring finger electrodes is from 332 μm to 1899 μm, and the relationship among the laid length L, the quantity N, the width W and the spacing G is interpreted by an equation of N×(W+G)−G=L.

2. The solar cell of claim 1, wherein, when the number of the busbars is 2 and the width W is from 10 to 20 μm, the spacing G is from 332 μm to 795 μm.

3. The solar cell of claim 1, wherein, when the number of the busbars is 2 and the width W is from 20 to 30 μm, the spacing G is from 652 μm to 1077 μm.

4. The solar cell of claim 1, wherein, when the number of the busbars is 2 and the width W is from 30 to 40 μm, the spacing G is from 881 μm to 1373 μm.

5. The solar cell of claim 1, wherein, when the number of the busbars is 2 and the width W is from 40 to 50 μm, the spacing G is from 1067 μm to 1588 μm.

6. The solar cell of claim 1, wherein, when the number of the busbars is 3 and the width W is from 10 to 20 μm, the spacing G is from 458 μm to 1014 μm.

7. The solar cell of claim 1, wherein, when the number of the busbars is 3 and the width W is from 20 to 30 μm, the spacing G is from 794 μm to 1383 μm.

8. The solar cell of claim 1, wherein, when the number of the busbars is 3 and the width W is from 30 to 40 μm, the spacing G is from 1003 μm to 1690 μm.

9. The solar cell of claim 1, wherein, when the number of the busbars is 3 and the width W is from 40 to 50 μm, the spacing G is from 1253m to 1783 μm.

10. The solar cell of claim 1, wherein, when the number of the busbars is 4 and the width W is from 10 to 20 μm, the spacing G is from 522 μm to 1174 μm.

11. The solar cell of claim 1, wherein, when the number of the busbars is 4 and the width W is from 20 to 30 μm, the spacing G is from 891 μm to 1526 μm.

12. The solar cell of claim 1, wherein, when the number of the busbars is 4 and the width W is from 30 to 40 μm, the spacing G is from 1077 μm to 1690 μm.

13. The solar cell of claim 1, wherein, when the number of the busbars is 4 and the width W is from 40 to 50 μm, the spacing G is from 1372 μm to 1899 μm.

14. The solar cell of claim 1, wherein, when the number of the busbars is 5 and the width W is from 10 to 20 μm, the spacing G is from 562 μm to 1274 μm.

15. The solar cell of claim 1, wherein, when the number of the busbars is 5 and the width W is from 20 to 30 μm, the spacing G is from 948 μm to 1526 μm.

16. The solar cell of claim 1, wherein, when the number of the busbars is 5 and the width W is from 30 to 40 μm, the spacing G is from 1163 μm to 1690 μm.

17. The solar cell of claim 1, wherein, when the number of the busbars is 5 and the width W is from 40 to 50 μm, the spacing G is from 1372 μm to 1899 μm.

18. The solar cell of claim 1, wherein the solar cell body has a plurality of the layout areas, and a length of the solar cell body along the first direction is less than a total of the laid lengths of the plurality of the layout areas.

19. The solar cell of claim 1, wherein the solar cell body has a plurality of lateral sides, and a buffer space exists between the layout area and the plurality of lateral sides.

20. The solar cell of claim 19, wherein the buffer space is from 0.1 to 2 mm.
